(19) United States
(12) Patent Application Publication
(10) Pub. No.: US 2026/0277114 A1
(43) Pub. Date: Sep. 17, 2026

(54) RECIPE TRANSFER OF PLASMA PROCESS USING PLASMA PARAMETERS DETERMINED BY VIRTUAL METROLOGY (VM) FEATURE SELECTION

(71) Applicant: TOKYO ELECTRON LIMITED, Tokyo (JP)

(72) Inventors: Jun SHINAGAWA, Fremont, CA (US); Inga KUZNETSOVA, Fremont, CA (US); Colin PILCHER, Hillsboro, OR (US); Megan WOOLEY, Austin, TX (US)

(73) Assignee: TOKYO ELECTRON LIMITED, Tokyo (JP)

(21) Appl. No.: 19/077,936

(22) Filed: Mar. 12, 2025

(51) Int. Cl. G03F 7/00; H01J 37/32

(52) U.S. Cl. CPC G03F 7/705; G03F 7/70525; H01J 37/32926; H01J 2237/334

(57) ABSTRACT

A method of process development includes obtaining, from plasma parameters associated with a plasma process, one or more selected plasma parameters by executing a virtual metrology (VM) feature selection process. A coupon recipe is obtained by adjusting a plasma process on a coupon sample based on the selected plasma parameters. The coupon sample includes a wafer coupon positioned on a carrier wafer. The coupon recipe is executed on a first whole wafer. A wafer recipe is obtained based on first values of the selected plasma parameters for the coupon recipe and the coupon sample, second values of the selected plasma parameters for the wafer recipe and the first whole wafer, and control models that describe relationships between the selected plasma parameters and recipe parameters of the plasma process. The wafer recipe is executed on a second whole wafer to determine whether the second whole wafer meets a pre-determined requirement.

### INCORPORATION BY REFERENCE

Aspects of the present disclosure are related to Applicant's issued patents, U.S. Pat. No. 12,112,107 B2, U.S. Pat. No. 11,869,756 B2, U.S. Pat. No. 10,622,219 B2 and U.S. Pat. No. 10,438,805 B2, all of which are incorporated herein by reference in their entirety.

### FIELD OF THE INVENTION

The present disclosure relates generally to methods of semiconductor manufacturing and particularly to virtual metrology (VM) for process development.

### BACKGROUND

In the manufacture of a semiconductor device (especially on the microscopic scale), various fabrication processes are executed such as film-forming depositions, etch mask creation, patterning, material etching and removal, and doping treatments. These processes are performed repeatedly to form desired semiconductor device elements on a substrate. During these fabrication processes, various recipes are executed in processing chambers, and semiconductor products (e.g. wafers) can be monitored and controlled using metrology tools. However, developing a reliable recipe for a given process to treat a plurality of substrates in a consistent manner is often challenging, time-consuming and cost-prohibitive.

### SUMMARY

The present disclosure relates to a method of process development and an apparatus of executing the same.

According to a first aspect of the disclosure, a method of process development is provided. The method includes obtaining, from plasma parameters associated with a plasma process, one or more selected plasma parameters by executing a virtual metrology (VM) feature selection process. A coupon recipe is obtained by adjusting a plasma process on a coupon sample based on the selected plasma parameters. The coupon sample includes a wafer coupon positioned on a carrier wafer. The coupon recipe is executed on a first whole wafer. A wafer recipe is obtained based on first values of the selected plasma parameters for the coupon recipe and the coupon sample, second values of the selected plasma parameters for the wafer recipe and the first whole wafer, and control models that describe relationships between the selected plasma parameters and recipe parameters of the plasma process. The wafer recipe is executed on a second whole wafer to determine whether the second whole wafer meets a pre-determined requirement.

In some embodiments, the executing the VM feature selection process includes determining key predictor parameters of the plasma process. A subset of the key predictor parameters are selected based on target metrology variables. A set of virtual metrology (VM) models are built on the subset of the key predictor parameters. A subset of the VM models are selected based on prediction accuracy. The selected plasma parameters are determined based on calculated feature importance.

In some embodiments, the determining the selected plasma parameters includes calculating feature importance values for variables with SHAP (SHapley Additive exPlanations) for each of the subset of the VM models and ranking the feature importance values to determine the selected plasma parameters.

In some embodiments, a multi-variant linear regression is executed with an exhaustive search for each target variable, which is cross-validated to select the subset of key predictor parameters.

In some embodiments, the set of VM models are built with an exhaustive search using cross-validation, and the set of VM models are ranked based on the prediction accuracy to select the subset of the VM models.

In some embodiments, the selected plasma parameters consist of one, two, three, four or five plasma parameters of interest.

In some embodiments, the determining the key predictor parameters includes determining a first subgroup of predictor parameters using domain knowledge including knowledge of the plasma process, a processing tool associated with the plasma process, a metrology tool, the coupon sample, the first whole wafer, or any combinations thereof. A second subgroup of predictor parameters are determined based on Design of Experiments (DOE) and the domain knowledge. A third subgroup of predictor parameters are obtained by processing manufacturing data collected from the processing tool. A fourth subgroup of predictor parameters are obtained by determining interaction terms of at least two predictor parameters selected from the group consisting of the first subgroup of predictor parameters, the second subgroup of predictor parameters and the third subgroup of predictor parameters, using the domain knowledge. A fifth subgroup of predictor parameters are obtained by processing the first subgroup of predictor parameters, the second subgroup of predictor parameters, the third subgroup of predictor parameters and the fourth subgroup of predictor parameters to generate interaction terms, mathematical transformation or any combinations thereof. Collinearity is removed among the first subgroup of predictor parameters, the second subgroup of predictor parameters, the third subgroup of predictor parameters, the fourth subgroup of predictor parameters and the fifth subgroup of predictor parameters to obtain the key predictor parameters.

In some embodiments, the obtaining the coupon recipe includes adjusting the recipe parameters of the plasma process so that the coupon sample, having been subjected to the coupon recipe obtained, meets the pre-determined requirement.

In some embodiments, the obtaining the wafer recipe includes determining difference between the first values of the selected plasma parameters for the coupon recipe and the coupon sample and the second values of the selected plasma parameters for the wafer recipe and the first whole wafer. A required change to the coupon recipe is determined based on the difference using the control models. The required change is added to the coupon recipe to obtain the wafer recipe.

In some embodiments, plasma parameters of interest and corresponding control models are obtained based on blanket film data of the plasma process. The selected plasma parameters are obtained by executing the VM feature selection process with coupon data of the plasma process on the coupon sample. When the plasma parameters of interest and the selected plasma parameters match with each other, the corresponding control models are selected as the control models.

In some embodiments, when the plasma parameters of interest and the selected plasma parameters do not match with each other, a new carrier wafer is provided.

In some embodiments, when the second whole wafer does not meet the pre-determined requirement, the selected plasma parameters are re-determined by re-executing the VM feature selection process.

In some embodiments, the obtaining the plasma parameters of interest and the corresponding control models includes executing a Design of Experiments (DOE) process on the blanket film data of the plasma process. The VM feature selection process is executed to determine the plasma parameters of interest. The corresponding control models are built for the plasma parameters of interest.

In some embodiments, a baseline recipe is executed respectively on a plurality of carrier wafer. The baseline recipe is executed on a third whole wafer. The carrier wafer is selected from the plurality of carrier wafers based on values of the selected plasma parameters for the third whole wafer and values of the selected plasma parameters for each of the plurality of carrier wafers.

In some embodiments, the plurality of carrier wafers are inspected to obtain at least a subset of carrier wafers that match with historic data to execute the baseline recipe on.

In some embodiments, when the second whole wafer meets the pre-determined requirement, the wafer recipe is executed on one or more additional whole wafers.

In some embodiments, the plasma process includes a plasma etching process, and the pre-determined requirement includes a target range of an etching rate.

In some embodiments, the carrier wafer is similar to the first whole wafer in terms of a mask material, a target etching material, an open area ratio, an aspect ratio, or a combination thereof.

In some embodiments, the mask material includes a hardmask material, and the target etching material includes silicon oxide or silicon nitride.

According to a second aspect of the disclosure, an apparatus is provided. The apparatus includes a controller which includes a processor that is programmed to obtain, from plasma parameters associated with a plasma process, one or more selected plasma parameters by executing a virtual metrology (VM) feature selection process, obtain a coupon recipe by adjusting a plasma process on a coupon sample based on the selected plasma parameters, execute the coupon recipe on a first whole wafer, obtain a wafer recipe based on first values of the selected plasma parameters for the coupon recipe and the coupon sample, second values of the selected plasma parameters for the wafer recipe and the first whole wafer, and control models that describe relationships between the selected plasma parameters and recipe parameters of the plasma process, and execute the wafer recipe on a second whole wafer to determine whether the second whole wafer meets a pre-determined requirement. The coupon sample includes a wafer coupon positioned on a carrier wafer.

Note that this summary section does not specify every embodiment and/or incrementally novel aspect of the present disclosure or claimed invention. Instead, this summary only provides a preliminary discussion of different embodiments and corresponding points of novelty. For additional details and/or possible perspectives of the invention and embodiments, the reader is directed to the Detailed Description section and corresponding figures of the present disclosure as further discussed below.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be increased or reduced for clarity of discussion.

FIG. 1A shows a schematic of a process for recipe transfer, in accordance with some embodiments of the present disclosure.

FIG. 1B shows a schematic of a process for recipe transfer, in accordance with some embodiments of the present disclosure.

FIG. 1C shows a schematic of a process for recipe transfer, in accordance with some embodiments of the present disclosure.

FIG. 1D shows a schematic of a process for recipe transfer, in accordance with some embodiments of the present disclosure.

FIGS. 2A, 2B and 2C show block diagrams of a feature selection process in accordance with some embodiments of the present disclosure.

FIG. 3 shows a block diagram of a carrier wafer selection process in accordance with some embodiments of the present disclosure.

FIG. 4 shows a block diagram of process development in accordance with some embodiments of the present disclosure.

FIG. 5 shows a block diagram of a feature selection process in accordance with some embodiments of the present disclosure.

FIG. 6 shows data of process development in accordance with some embodiments of the present disclosure.

FIG. 7 shows a flow chart of a process for recipe transfer in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed. Further, spatially relative terms, such as “top,” “bottom,” “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The order of discussion of the different steps as described herein has been presented for clarity's sake. In general, these steps can be performed in any suitable order. Additionally, although each of the different features, techniques, configurations, etc. herein may be discussed in different places of this disclosure, it is intended that each of the concepts can be executed independently of each other or in combination with each other. Accordingly, the present invention can be embodied and viewed in many different ways.

In the drawings, like reference numerals designate identical or corresponding parts throughout the several views. Additionally, as used herein, the words “a”, “an” and the like generally carry a meaning of “one or more”, unless stated otherwise.

Furthermore, the terms, “approximately”, “approximate”, “about” and similar terms generally refer to ranges that include the identified value within a margin of 20%, 10%, or preferably 5%, and any values therebetween.

A numerical range represented by “to”, “from . . . to . . . ”, “-” and similar terms includes numerical values at both ends, unless specified otherwise.

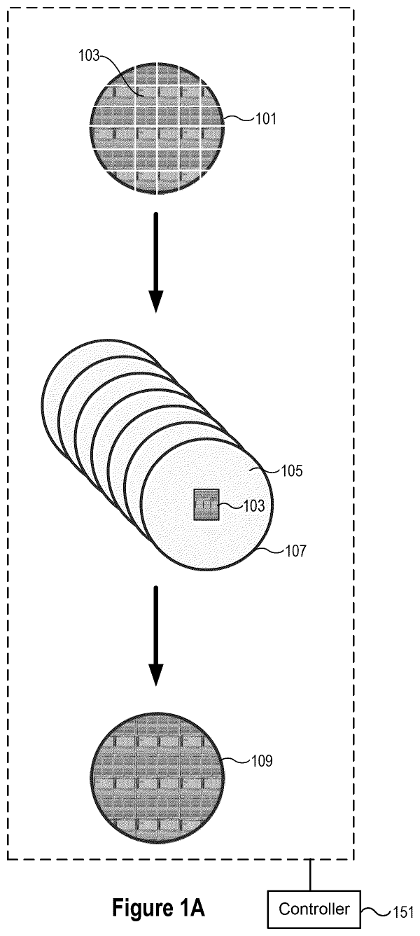

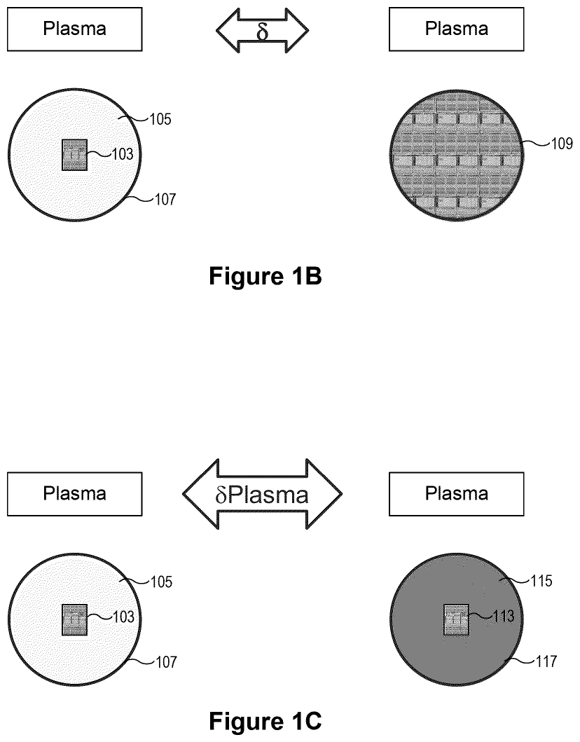

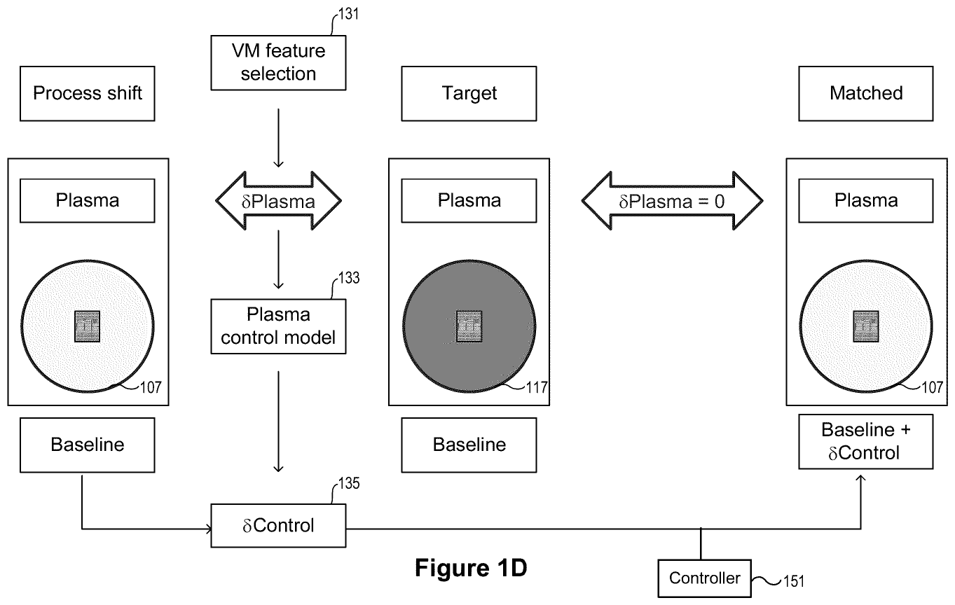

As noted in the Background, it is challenging to develop a reliable recipe for a given semiconductor process such as a plasma process to treat a plurality of substrates in a consistent manner. FIG. 1A shows a schematic of a process for recipe development or transfer, in accordance with some embodiments of the present disclosure. As illustrated, a wafer coupon 103 in the form of a small section cut from an initial wafer 101 can be used for testing and quality control purposes during the manufacturing process, allowing technicians to evaluate the wafer's properties without having to test the entire wafer each time. In other words, the wafer coupon 103 can function as a sample piece taken from the initial wafer 101 to test a recipe and/or analyze specific aspects of the initial wafer 101 (e.g. etching rates, surface quality, or material characteristics) before proceeding with full chip fabrication on a wafer level.

In the process of developing a wafer recipe, a coupon recipe can be developed first. Specifically, the wafer coupon 103 can be placed on a carrier wafer 105 to form a coupon sample 107. For example, the wafer coupon 103 may be glued to the carrier wafer 105 via a tape, an adhesive or the like. Then, a semiconductor process or a plasma process such as a plasma etching process can be executed and tested on the coupon sample 107. Conditions of the semiconductor process can be adjusted or optimized to develop a coupon recipe so that the coupon sample 107 having been subjected to the coupon recipe meet one or more specifications e.g. a target range of etching rate, critical dimension, etc.

Then the coupon recipe can be transferred to a whole wafer 109. In one example, the coupon recipe is used directly as a wafer recipe for the whole wafer 109. In another example, the coupon recipe is used as a starting point to develop a wafer recipe, which will be explained in detail later in the present disclosure.

In some embodiments, the whole wafer 109 can be a production wafer that is used in real production to manufacture semiconductor devices, integrated circuits, etc. A production wafer often has patterns of semiconductor, metal and/or dielectric materials formed thereon. The carrier wafer 105 is often not used in real production but used for testing and development purposes. As a result, the carrier wafer 105 may or may not have patterns formed thereon. The carrier wafer 105 can have a top surface blanket film such as silicon, silicon oxide or silicon nitride. The carrier wafer 105 can be a used or recycled wafer. The carrier wafer 105 is often chosen to have a same size or diameter as the whole wafer 109. The initial wafer 101 can be a production wafer. Particularly, the initial wafer 101 and the whole wafer 109 can be two production wafers that have been subjected to similar or the same prior semiconductor process(es) e.g. film-forming depositions, etch mask creation, patterning, material etching, doping, etc.

Additionally, a controller 151 may be included in the example of FIG. 1A. Components of a corresponding plasma tool can be connected to and controlled by the controller 151 that may optionally be connected to a corresponding memory storage unit and user interface (all not shown). Various plasma-processing operations can be executed via the user interface, and various plasma processing recipes and operations can be stored in a storage unit. Accordingly, a given substrate can be processed within a plasma chamber with various microfabrication techniques.

It will be recognized that the controller 151 may be coupled to various components of the corresponding plasma tool to receive inputs from and provide outputs to the components. For example, the controller 151 can be configured to receive measured values of various plasma parameters from a corresponding plasma tool. The controller 151 can also be configured to adjust knobs and control settings for the corresponding plasma tool. Of course the adjustments can be manually made as well.

It will also be recognized that the controller 151 may be coupled to various components and/or steps of the process in FIG. 1A to receive inputs from and provide outputs to the components. For example, the controller 151 can be configured to cut the initial wafer 101 and obtain the wafer coupon 103. The controller 151 can also be configured to test, adjust and/or optimize the coupon recipe on the coupon sample 107. The controller 151 can further be configured to transfer the coupon recipe to the whole wafer 109 and/or develop the wafer recipe, which will be explained later. Of course, one or more functions of the controller 151 can also be manually accomplished.

The controller 151 can be implemented in a wide variety of manners. In one example, the controller 151 is a computer. In another example, the controller 151 includes one or more programmable integrated circuits that are programmed to provide the functionality described herein. For example, one or more processors (e.g. microprocessor, microcontroller, central processing unit, etc.), programmable logic devices (e.g. complex programmable logic device (CPLD)), field programmable gate array (FPGA), etc.), and/or other programmable integrated circuits can be programmed with software or other programming instructions to implement the functionality of a plasma process recipe. It is further noted that the software or other programming instructions can be stored in one or more non-transitory computer-readable mediums (e.g. memory storage devices, FLASH memory, DRAM memory, reprogrammable storage devices, hard drives, floppy disks, DVDs, CD-ROMs, etc.), and the software or other programming instructions when executed by the programmable integrated circuits cause the programmable integrated circuits to perform the processes, functions, and/or capabilities described herein. Other variations could also be implemented.

FIG. 1B shows a schematic of a process for recipe development or transfer, in accordance with some embodiments of the present disclosure. Herein, the coupon recipe developed from the coupon sample 107 is used directly as a wafer recipe for the whole wafer 109, which may not be reliable. For example, during process development, variations in open area ratio (OAR) of mask to target films often result in process profile shifts due to variations in consumption of radical species and by-product generations. Such problems can occur when transferring the recipe developed with the wafer coupon 103 on the carrier wafer 105 to the whole wafer 109. This can be investigated by for example characterizing plasma parameters while executing the coupon recipe respectively on the coupon sample 107 and on the whole wafer 109.

FIG. 1C shows a schematic of a process for recipe development or transfer, in accordance with some embodiments of the present disclosure. Herein, a coupon sample 117 includes a wafer coupon 113 and a carrier wafer 115. The wafer coupon 103 and the wafer coupon 113 can both be sourced from the initial wafer 101. The carrier wafer 105 and the carrier wafer 115 can have a same size or diameter, with however different top surface materials. For instance, the carrier wafer 105 can have silicon oxide as its top surface material in the form of a blanket film, whereas the carrier wafer 115 can have bare silicon as its top surface material. An open area ratio (OAR) can be defined as an areal ratio of film deposited on bare silicon. Accordingly, an OAR of the coupon sample 107 is 100% while an OAR of the coupon sample 117 is 0%. When the coupon recipe developed from the coupon sample 107 is used directly for the coupon sample 117, difference in plasma or plasma parameters may exist between the coupon sample 107 and the coupon sample 117.

Techniques herein can speed up the process development time by providing clear metrics (e.g. plasma parameters) to tune process recipes and reduce the amount of metrology (e.g. scanning electron microscopy and transmission electron microscopy) necessary to determine optimal conditions. To simplify process transfer from a coupon to a whole wafer, the fewest number of plasma parameters are selected to tune. Techniques herein provide a standardized and quantitative way to transfer coupon conditions to a whole wafer. Techniques herein can be used to select the best carrier wafer configuration for process development with a coupon on a carrier wafer.

According to aspects of the present disclosure, identification of plasma parameters impacting plasma etch profile variations can be accomplished by virtual metrology (VM) feature selection. For example, VM technology can be applied to enable process engineers to fine-tune process recipes. Feature selection can also be used to narrow down on plasma parameters.

FIG. 1D shows a schematic of a process for recipe development or transfer, in accordance with some embodiments of the present disclosure. In box 131, a virtual metrology (VM) feature selection process based on the aforementioned difference in plasma or plasma parameters can be executed to select plasma parameters of interest.

In box 133, a plasma control model is used to determine a required change to the coupon recipe based on the difference. For example, the plasma control model can express at least one plasma parameters (e.g. radical concentration) as a function of at least one recipe parameter (e.g. gas flow rate) or vice versa. Therefore, the difference in plasma can be converted to a required change to the coupon recipe. Generally speaking, a recipe parameter can be a parameter in a recipe that can be adjusted for example by using a knob of a plasma tool. Examples of a recipe parameter include, but are not limited to, gas flow rate, gas type, microwave power, electrostatic chuck temperature and the like. A plasma parameter can be a measure of a plasma and affected by the recipe. Examples of a plasma parameter include, but are not limited to, gas pressure, gas temperature, species concentration, etchant flux, deposition flux, by-product re-deposition rate, a sticking coefficient, ion flux, ion energy, etc. A control model can describe a relationship between at least one recipe parameter and at least one plasma parameter. Therefore, a change in plasma can be converted to a change in the recipe by using the control model.

In box 135, the required change noted as δControl is added to the coupon recipe so that plasma for the coupon sample 107 subjected to the changed coupon recipe and target plasma for the coupon sample 117 can be matched. Various components and/or steps of the process in FIG. 1D can be coupled to the controller 151.

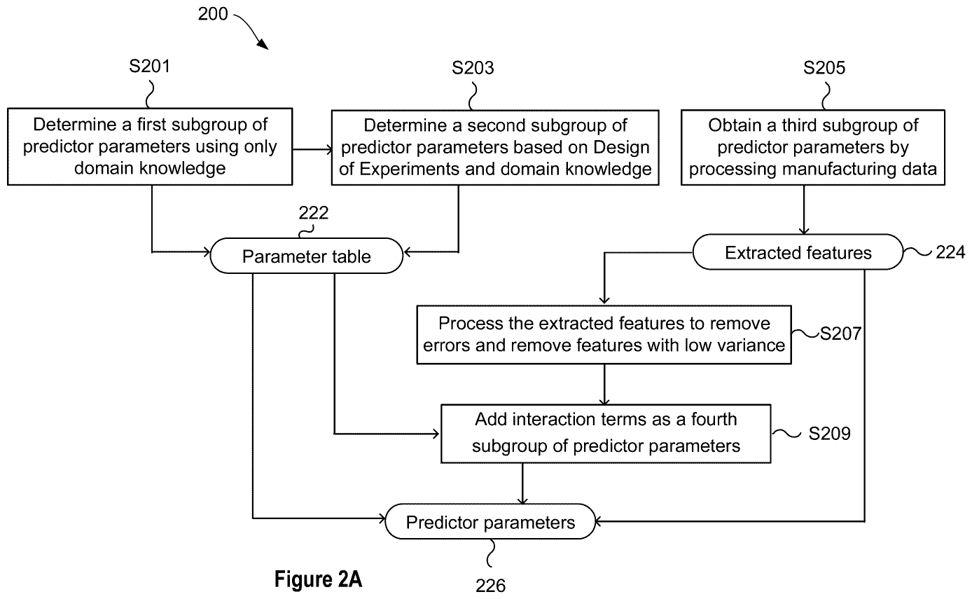

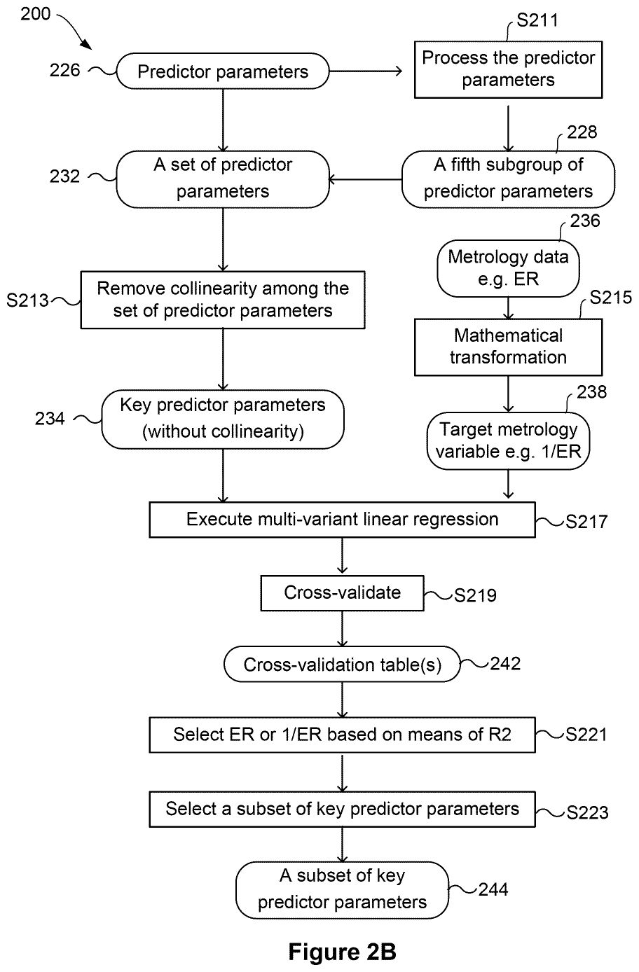

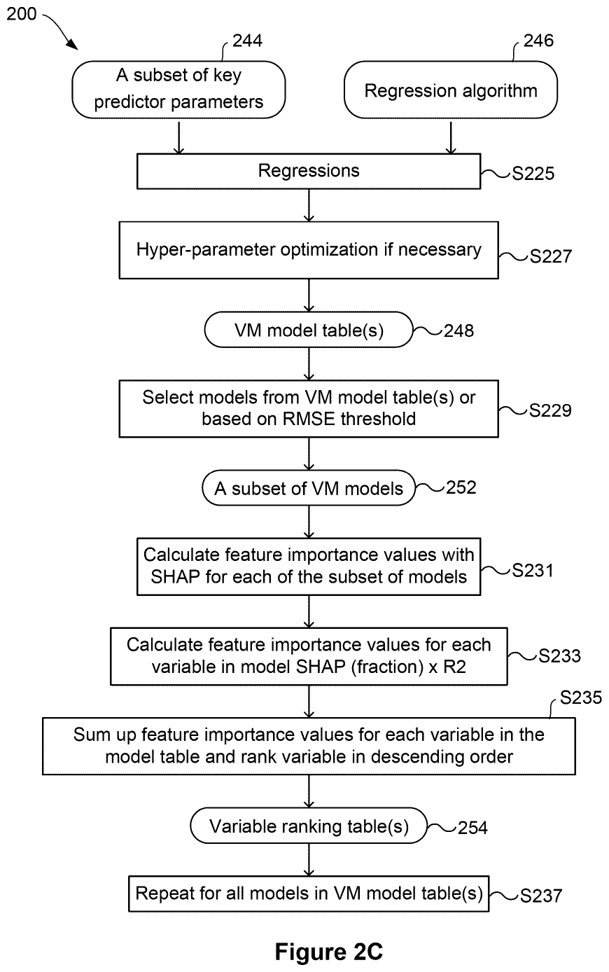

FIGS. 2A, 2B and 2C show block diagrams of a feature selection process (hereinafter referred to as a process 200) in accordance with some embodiments of the present disclosure. Some aspects of the process 200 are described in Applicant's issued U.S. Pat. No. 12,112,107 B2, which is incorporated herein by reference in its entirety.

One goal of the process 200 is to reduce the number (e.g. identifying the minimal number) of plasma parameters that will be tuned to match process results between the coupon sample 107 and the whole wafer 109 within required specifications (usually set by a user or customer). There is no need to achieve perfect matching as long as the required specifications are met. Inventors of the present disclosure have discovered that only a few plasma parameters may be needed that are impacted by difference in OAR between the coupon sample 107 and the whole wafer 109 such as chemical species mainly.

By reducing the number of plasma parameters needed, there will be less complication on improving or optimizing a recipe. The number of predictors or predictor parameters in regression models can be reduced or limited as there is no need to identify many plasma parameters. Techniques herein may use up to 5 (e.g. 1, 2, 3, 4 or 5) or more predictors in feature selection. Preferably, 1, 2 or 3 predictors are used in feature selection, which in turn allow a user to run exhaustive search regression which could be computationally very expensive as the number of predictors increases in traditional techniques. The number of variables remained after subset selection can also be reduced or limited.

At step S201, a first subgroup of predictor parameters is determined using domain knowledge. The domain knowledge can for example include knowledge of the plasma process, a plasma tool associated with the plasma process, a metrology tool, a workpiece (e.g. a wafer coupon, a wafer coupon on a carrier wafer, a whole wafer, etc.) or any combinations thereof so that the first subgroup of predictor parameters is expected to affect wafer results. In some embodiments, knowledge of the plasma process can include physical characteristics, chemical characteristics, and/or other information of the plasma process, such as atomic and molecular dissociation in plasma, surface reaction model, and plasma diagnostics. Knowledge of the plasma tool can include a recipe for the plasma process, information of a plasma chamber, and/or other information related to the plasma tool, such as recipe parameters. Knowledge of the metrology tool can include a measurement method and/or other information related to the plasma tool, such as actinometry for optical emission spectroscopy. Knowledge of the wafer can include information of a film of the wafer, a substrate of the wafer, and/or the like, such as chemical composition of an exposed film. The domain knowledge can be obtained by collecting prior knowledge in literature, common knowledge within a plasma industry/academia, professional knowledge of a plasma expert, and the like.

Particularly, in a plasma etching process, the domain knowledge can include etching mechanism, plasma chamber information, recipe information, wafer information, depth measurement method information, and/or the like. By using any of the domain knowledge, such as etching mechanism, a parameter expected to affect wafer results (e.g., an etching rate or a critical dimension) can be added to the first subgroup of predictor parameters. In an embodiment where an etching byproduct reduces the etching rate, a parameter related to the etching byproduct may be added to first subgroup of predictor parameters. Other parameters, such as chlorine density and oxygen density, can also be added to first subgroup of predictor parameters.

At step S203, a second subgroup of predictor parameters are determined based on Design of Experiments (DOE) and the domain knowledge. For example, sensitivities of a recipe parameter at a recipe step to a target metric (e.g. the etching rate or the critical dimension) can be determined by DOE, and the recipe parameter is selected based on a sensitivity threshold. Next, a plasma parameter corresponding to the selected recipe parameter is identified by referencing to a plasma parameter library, which is another example of domain knowledge. For example, a flow rate of oxygen in the recipe corresponds to an atomic oxygen density in the plasma process. Then, combining the above plasma parameters results in the second subgroup of predictor parameters. Therefore, the second subgroup of predictor parameters is known to affect wafer results and is a subset of the first subgroup of predictor parameters. In some embodiments, the first subgroup of predictor parameters is then removed from the second subgroup of predictor parameters. Additionally, DOE can be analyzed and implemented in many software programs, such as JMP. In some embodiments, the first subgroup of predictor parameters and the second subgroup of predictor parameters are combined to form a parameter table 222.

At step S205, a third subgroup of predictor parameters that are associated with the plasma process are obtained by processing manufacturing data collected from the plasma tool. The third subgroup of predictor parameters can be noted as extracted features 224. The plasma tool can, for example, include a chemical vapor deposition system, a sputtering system, an ion implantation system, and the like. Particularly, in the plasma etching process example mentioned above, the plasma tool includes an etching system. Manufacturing data including time trace data associated with settings of the plasma tool (e.g., a gas flow rate) and/or the plasma process (e.g., an optical emission spectrum), can be collected from the plasma tool. The time trace data are then processed to obtain the third subgroup of predictor parameters that have physical or chemical meanings related to the plasma etching process. In an embodiment, a mean gas flow rate is obtained by calculating the time average gas flow rate and provides information about average etching conditions. In another embodiment, emergence/disappearance of a certain peak in the optical emission spectrum may indicate the onset/endpoint of an etching reaction.

As step S207, the exacted features 224 are then processed to remove errors and remove features with low variance. For example, a variance threshold can be pre-determined depending on specific design needs, and features with variance below the variance threshold can be removed. In some embodiments, variance includes changes in feature values which can be correlated with variations in one or more target variables e.g. etching rate, etc. Errors may include random or systematic variations originated from e.g. one or more sensors. Particularly, outliers (data points deviate significantly from mean trend) and parameters with small variations can be removed at this step. In other words, errors and features with low variance are removed, while features with variance equal to or above the variance threshold are kept.

At step S209, the domain knowledge is used to add interaction terms of at least two predictor parameters selected from the group consisting of the first subgroup of predictor parameters, the second subgroup of predictor parameters and the third subgroup of predictor parameters as a fourth subgroup of predictor parameters. Hence, the fourth subgroup of predictor parameters is non-linear. In some embodiments, an interaction term can be a product, a division, and/or another mathematical operation of two or more predictor parameters of the first, second, and third subgroups. In the above-mentioned example of the plasma etching process, interaction terms can include the division of chlorine density by oxygen density.

Then predictor parameters 226 can be obtained by combining the parameter table 222, the extracted features 224, and the interaction terms obtained at step S209. Note that, in some embodiments, two or three subgroups may share a common parameter. The common parameter is noted as a single parameter in the predictor parameters 226 when the four subgroups are combined. Therefore, the predictor parameters 226 include the first, second, third, and fourth subgroups of predictor parameters.

In FIG. 2B, the predictor parameters 226 are (pre-) processed at step S211 to obtain a fifth subgroup of predictor parameters 228. For example, an interaction term can be generated in the form of a product, a division, and/or another mathematical operation of two or more predictor parameters of the predictor parameters 226. In the above-mentioned example of the plasma etching process, interaction terms can include the division of CF₂ density by oxygen density, cCF₂/nO, an inverse of F density, 1/nF, etc. The fifth subgroup of predictor parameters 228 can be added to the predictor parameters 226 to form a set of predictor parameters 232.

At step S213, collinearity is removed among the set of predictor parameters 232 to form key predictor parameters 234. Collinearity removal can be accomplished by calculating correlations between one predictor parameter and other predictor parameters, and then grouping predictor parameters based on correlations. In other words, one or more predictor parameters are grouped together with respective correlations meeting a threshold requirement. Subsequently, a representative predictor parameter is selected from each group to form the key predictor parameters 234. Consequently, the key predictor parameters can have fewer parameters than the set of predictor parameters 232. Moreover, the key predictor parameters 234 have no collinearity with one another. In some embodiments, the aforementioned five subgroups of predictor parameters can be assigned different priorities. For example, the representative predictor parameter can be selected in order of priority: the second subgroup (a first priority), the first and fifth subgroups (a second priority), and the third and fourth subgroups (a third priority). Therefore, parameters from a subgroup of a higher priority (e.g. the first priority) are more likely to be selected as one of the key predictor parameters than parameters from a subgroup of a lower priority (e.g. the third priority). Parameters from a subgroup of a lower priority (e.g. the third priority) are more likely to be removed than parameters from a subgroup of a higher priority (e.g. the first priority). In some embodiments, a ranking system may be implemented within one or more subgroups of predictor parameters.

Metrology data 236 can be collected from at least one metrology tool and show wafer results of interest. The metrology tool(s) may include electrical, optical, and/or analytical tools, such as resistivity measurement tools, film thickness measurement tools, optical microscopes, transmission/scanning electron microscopes, and other test and measurement tools. The metrology data 236 may include various wafer characteristics measured by the metrology tool(s), such as sheet resistance, reflectivity, and the like. Particularly, in the plasma etching process example above, the metrology data 236 can include an etching rate (ER) and/or a critical dimension (CD). At step S215, a mathematical transformation can be performed on the metrology data 236 to obtain one or more target metrology variables e.g. 1/ER.

At step S217, a multi-variant linear regression can be executed for example with an exhaustive search for each target variable for a number of input variables (p) from 1 to 4. At step S219, a cross-validation process is executed to obtain one or more cross-validation tables 242 such as Tables 1 and 2 below. LM stands for a linear regression model using the lm( ) function in R.

TABLE 1
Cross-validation table for ER
ER

| | Regression | | | | |
|---|---|---|---|---|---|
| R2 | algorithm | Var 1 | Var2 | Var3 | Var4 |
| 0.6 | LM | nCF₂/nO | nₑ | nF | nO |
| 0.5 | LM | nCF₂ | nₑ | | |
| 0.4 | LM | nCF₂/nO | nO | | |
| 0.35 | LM | nCF₂/nO | | | |
| | | . . . | | | |

TABLE 2
Cross-validation table for 1/ER
1/ER

| | Regression | | | | |
|---|---|---|---|---|---|
| R2 | algorithm | Var1 | Var2 | Var3 | Var4 |
| 0.9 | LM | 1/nCF₂ | 1/nₑ | 1/nF | 1/nO |
| 0.87 | LM | nCF₂ | 1/nₑ | | |
| 0.8 | LM | nCF₂/nO | nO | | |
| 0.5 | LM | nCF₂/nO | | | |
| | | . . . | | | |

At step S221, ER or 1/ER can be selected based on the mean value of R² of all the regression models generated. At step S223, a subset 244 of key predictor parameters can be selected based on the one or more cross-validation tables 242.

In FIG. 2C, regressions can be performed at step S225 for the subset 244 of key predictor parameters using regression algorithm 246 to obtain at least one virtual metrology (VM) model table 248. The regression algorithm 246 can include Gaussian Process (GP), Random Forest (RF), etc. As a result, regression models or VM models can be built for example with an exhaustive search with fewer than 5 predictors using cross-validation. At step S227, hyper-parameter optimization can be optionally performed if desired or necessary. Table 3 below is one example of a VM model table 248 ranking VM models according to prediction accuracy. RMSE stands for Root Squared Mean Error, which is a measure of prediction error. Generally speaking, the smaller RSME, the better prediction. An RSME threshold can be set by accuracy requirement for prediction models or arbitrarily. GP1 stands for GP with kernel-1. GP2 stands for GP with kernel-2.

TABLE 3
VM models ranked by prediction accuracy
1/ER

| | Regression | | | | |
|---|---|---|---|---|---|
| RMSE | algorithm | Var1 | Var2 | Var3 | Var4 |
| 0.5 | GP1 | 1/nCF₂ | 1/nₑ | 1/nF | 1/nO |
| 1 | RF | nCF₂ | 1/nₑ | | |
| 1.2 | GP2 | nCF₂/nO | nO | | |
| 2 | LM | nCF₂/nO | | | |
| | | . . . | | | |

At step S229, a subset of VM models 252 can be selected. In one example, a fixed number of VM models can be selected from the VM model table 248 from top rows. In another example, all VM models within an RMSE threshold are selected.

At step S231, feature importance values can be calculated with SHAP (SHapley Additive explanations) for each of the subset of VM models 252. At step S233, feature importance values can be calculated for each variable in model SHAP (fraction)×R². At step S235, the feature importance values are summed up for each variable in the VM model table 248, and variables can be ranked in descending order to obtain one or more variable ranking tables 254. At step S237, variable ranking can be repeated for all models in the VM model table 248. Tables 4 and 5 below are two examples of the one or more variable ranking tables 254. Table 5 may correspond to GP2 model in Table 3. “SHAP (fraction)” stands for a fraction value of a total mean value.

TABLE 4
Variable ranking

| | | Feature |
|---|---|---|
| | | importance |
| Rank | Feature | value |
| 1 | nCF₂/nO | 12.1 |
| 2 | nCF₂ | 6 |
| 3 | nO | 2 |
| 4 | nₑ | 0.5 |
| | . . . | |

TABLE 5
Variable ranking

| | | | Feature |
|---|---|---|---|
| | | SHAP | importance |
| RMSE | Variable | (fraction) | value |
| 1.2 | nCF₂/nO | 0.71 | 0.85 |
| | nO | 0.29 | 0.35 |

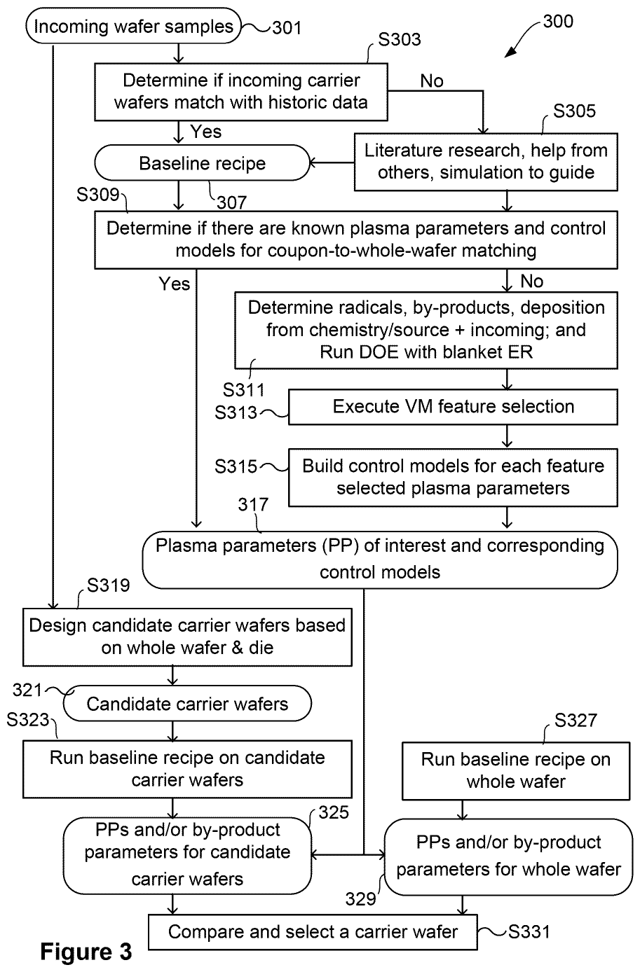

FIG. 3 shows a block diagram of a carrier wafer selection process (hereinafter referred to as a process 300) in accordance with some embodiments of the present disclosure. At step S303, whether incoming wafer samples 301 match with historic data is determined. The incoming wafer samples 301 can include whole wafers or production wafers as previous discussed. A user may collect information regarding the incoming wafer samples 301 including, but not limited to, target etching material, mask material, an aspect ratio and an open area ratio on a die level as well as an open area ratio and uniformity on a whole wafer level. The historic data may include wafer characteristics or wafer properties of previously processed production wafers such as previously worked layers.

When the incoming wafer samples 301 does not match with the historic data, a user may conduct a literature research study, seek help from a (senior) colleague, conduct simulations for guidance, etc. to design or obtain a baseline recipe 307. When the incoming wafer samples 301 match with the historic data, the baseline recipe 307 can be obtained, for example by retrieving a historic recipe from historic processes. The baseline recipe 307 is not particularly limited and can be any historic recipe that meets certain requirements.

At step S309, whether there are known plasma parameters and control models for coupon-to-whole-wafer matching is determined. When there are, plasma parameters of interest and corresponding control models 317 can be obtained or selected from the known plasma parameters and control models. When there are no such known plasma parameters and control models, the process 300 proceeds to step S311 to determine radicals, by-products, deposition from chemistry/source+incoming and run DOE with blanket film ER. At step S313, a VM feature selection process (e.g. the process 200) can be executed to obtain or select the plasma parameters of interest (e.g. 317). At step S315, the corresponding control models (e.g. 317) can be built for each of the plasma parameters of interest.

At step S319, candidate carrier wafers 321 can be designed based on whole-wafer and die information of the incoming wafer samples 301 as discussed above. In some embodiments, the candidate carrier wafers 321 can be designed based on production wafers. Consider FIG. 1A for example. The carrier wafer 105 can be designed to resemble a die of the initial wafer 101 or the initial wafer 101. For instance, the initial wafer 101 may include a hardmask material patterned on silicon oxide. The carrier wafer 105 can thus be designed to have the hardmask material and silicon oxide. An exposed areal ratio of the hardmask material to silicon oxide of the carrier wafer 105 can be similar or identical to that of the initial wafer 10, with or without the same pattern formed. As a result, the candidate carrier wafers 321 can be obtained. The candidate carrier wafers 321 may each exhibit a gradient of some properties for optimization purposes.

At step S323, the baseline recipe 307 is executed on the candidate carrier wafers 321. Values 325 for the plasma parameters of interest and/or byproduct properties can be collected for the candidate carrier wafers 321. At step S327, the baseline recipe 307 is executed on one or more whole wafers. Values 329 for the plasma parameters of interest and/or byproduct properties can be collected for the one or more whole wafers. At step S331, the values 325 and the values 329 can be compared to select a carrier wafer from the candidate carrier wafers 321 for example based on difference between the values 325 and the values 329. Alternatively or additionally, a carrier wafer can be selected such that a minimum number of recipe variables are necessary.

In some embodiments, the values 325 can include values for all plasma parameters associated with the plasma etching process and byproduct properties for the candidate carrier wafers 321. The values 329 can include values for all plasma parameters associated with the plasma etching process and byproduct properties for the one or more whole wafers.

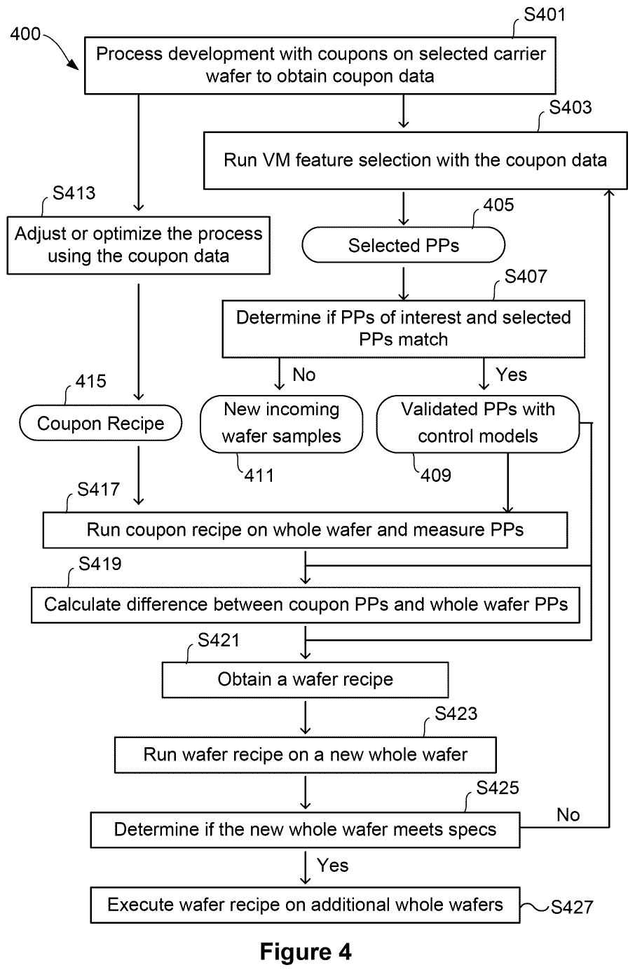

FIG. 4 shows a block diagram of a process 400 for process development in accordance with some embodiments of the present disclosure. At step S401, the plasma etching process can be respectively executed on a plurality of wafer coupons on the carrier wafer selected at step S331 to obtain coupon data. At step S403, a VM feature selection process (e.g. the process 200) can be executed based on the coupon data to obtain selected plasma parameters 405 for example from (all) plasma parameters associated with the plasma etching process.

At step S407, whether the plasma parameters of interest (e.g. 317) and the selected plasma parameters 405 match with each other (e.g. including the same plasma parameters) is determined. If so, the plasma parameters of interest (e.g. 317) and the selected plasma parameters 405 are validated and used as validated parameters. Accordingly, the corresponding control models (e.g. 317) are used as validated control models 409. When the plasma parameters of interest (e.g. 317) and the selected plasma parameters 405 do not match, new incoming wafer samples 411 are needed to at least partially repeat the process 300. In other words, the process 300 may be at least partially repeated with the new incoming wafer samples 411 in lieu of the incoming wafer samples 301 to obtain new plasma parameters of interest and new corresponding control models and/or obtain a new carrier wafer.

At step S413, the plasma etching process is adjusted or optimized using the coupon data and the coupon sample to obtain a coupon recipe 415 so that a coupon sample (e.g. 107) having been subjected to the coupon recipe 415 can meet the one or more specifications e.g. a target range of etching rate, critical dimension, etc. The coupon recipe 415 may or may not be an optimized recipe as long as one or more predetermined specifications are met.

At step S417, the coupon recipe 415 can be executed on a whole wafer (e.g. 109) during which process the validated parameters are measured and referred to as whole-wafer plasma parameters. Similarly, the validated parameters for a coupon sample (e.g. 107) can be measured during step S413 and referred to as coupon plasma parameters. Alternatively, the validated control models 409 can be used to derive or determine the coupon plasma parameters based on the coupon recipe 415. Note that the coupon plasma parameters may also be referred to as first values of the selected plasma parameters for the coupon recipe and the coupon sample, while the whole-wafer plasma parameters may also be referred to as second values of the selected plasma parameters for the wafer recipe and the first whole wafer.

At step S419, difference between the coupon plasma parameters and the whole-wafer plasma parameters are calculated. At step S421, a wafer recipe is obtained based on the coupon recipe 415 and the difference between the coupon plasma parameters and the whole-wafer plasma parameters. For instance, the difference between the coupon plasma parameters and the whole-wafer plasma parameters can be used to determine a required change to the coupon recipe using the validated control models 409. Then, the required change is added to the coupon recipe 415 to obtain the wafer recipe.

At step S423, the wafer recipe is executed on a new whole wafer (e.g. 109). At step S425, whether the new whole wafer having been subjected to the wafer recipe meets the aforementioned specifications is determined. If so, the wafer recipe can be determined to be a valid recipe for whole wafers. Accordingly at step S427, the wafer recipe can therefore be executed on one or more additional whole wafers (e.g. 109). However, when the new whole wafer having been subjected to the wafer recipe does not meet the specifications, the process 400 may return to step S403.

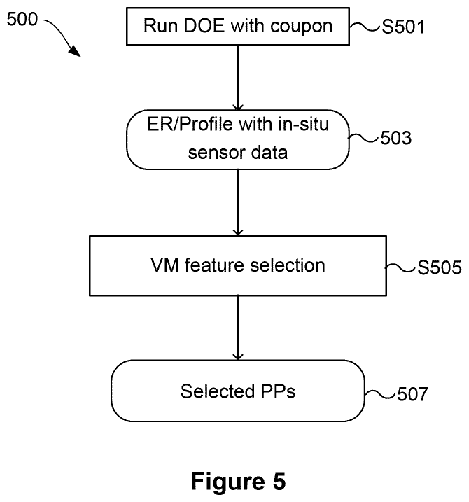

FIG. 5 shows a block diagram of a feature selection process (hereinafter referred to as a process 500) in accordance with some embodiments of the present disclosure. At step S501, DOE can be executed on coupon samples (e.g. 107) to obtain ER/profile with in-situ sensor data 503. At step S505, a VM feature selection process is executed to obtain selected plasma parameters 507. For example, step S505 can be accomplished by the process 200, and the selected plasma parameters 507 may correspond to the selected plasma parameters 405.

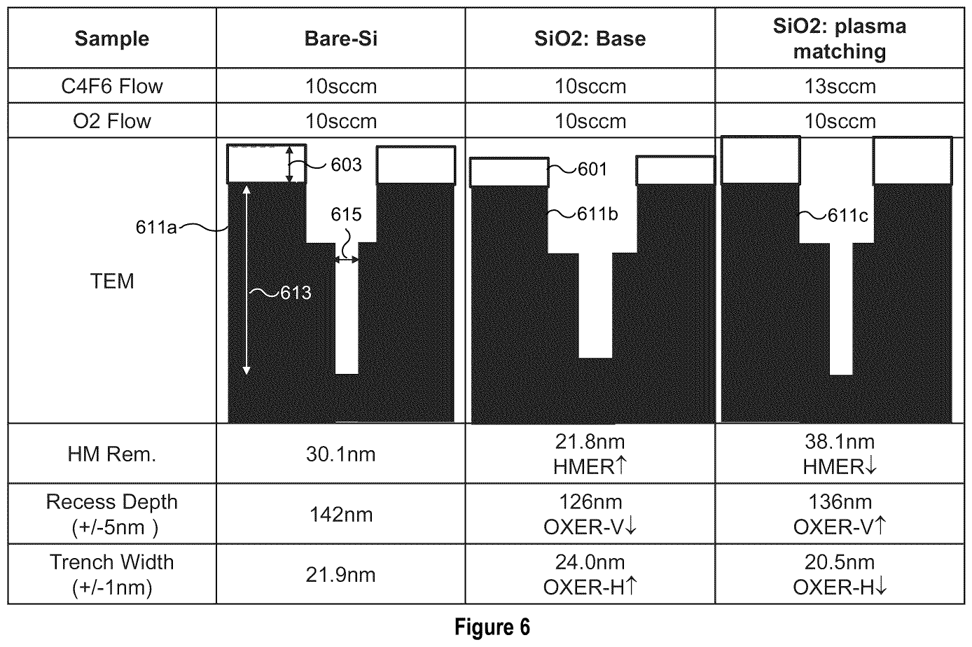

FIG. 6 shows data of process development in accordance with some embodiments of the present disclosure. Herein, a hardmask material 601 is deposited and patterned over a target etching material e.g. 611a, 611b and 611c. “HM Rem.” refers to a remaining thickness 603 of the hardmask material 601 after plasma etching. “Recess Depth” is shown by 613. “Trench Width” is shown by 615. In a non-limiting example, target etching materials 611a, 611b and 611c are respectively silicon, silicon oxide and silicon oxide. Columns of “Bare-Si”, “SiO2: Base” and “SiO2: plasma matching” in FIG. 6 can respectively correspond to columns represented by “Target”, “Process shift” and “Matched” in FIG. 1D.

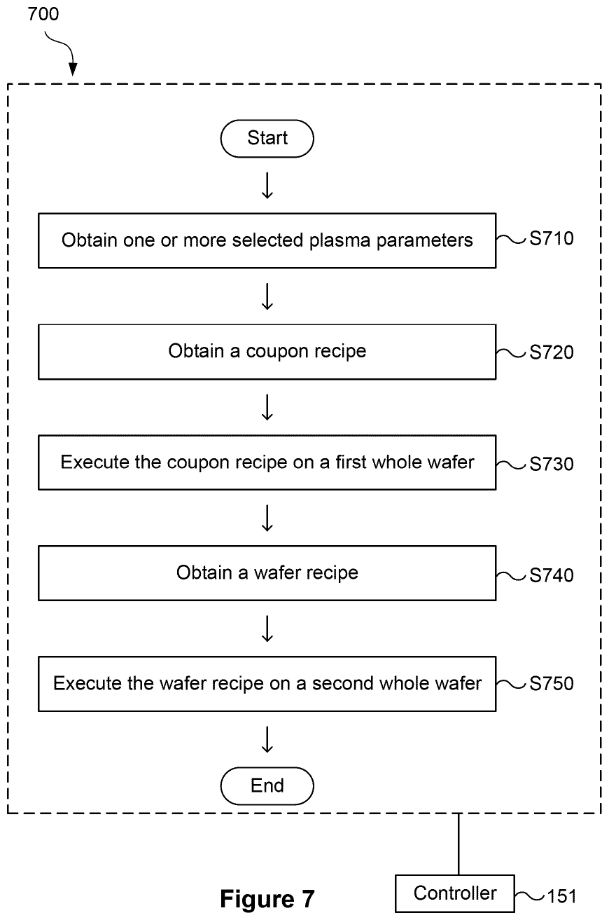

FIG. 7 shows a flow chart of a process 700 for recipe development or transfer in accordance with some embodiments of the present disclosure. At step S710, one or more selected plasma parameters are obtained from plasma parameters associated with a plasma process by executing a virtual metrology (VM) feature selection process. At step S720, a coupon recipe is obtained by adjusting a plasma process on a coupon sample based on the selected plasma parameters. The coupon sample includes a wafer coupon positioned on a carrier wafer. At step S730, the coupon recipe is executed on a first whole wafer. At step S740, a wafer recipe is obtained based on first values of the selected plasma parameters for the coupon recipe and the coupon sample, second values of the selected plasma parameters for the wafer recipe and the first whole wafer, and control models that describe relationships between the selected plasma parameters and recipe parameters of the plasma process. At step S750, the wafer recipe is executed on a second whole wafer to determine whether the second whole wafer meets a pre-determined requirement.

Optionally, the controller 151 may be coupled to various components of the process 700 to receive inputs from and provide outputs to the components. For example, the controller 151 can be configured to implement steps S710, S720, S730, S740 and/or S750. Of course, one or more functions of the controller 151 can also be manually accomplished.

While the controller 151 is not shown in every figure of the present disclosure for simplicity purposes, it should be understood that the controller 151 can be included in embodiments of every figure of the present disclosure and coupled to various components thereof, similar to FIGS. 1, 3 and 7 as discussed above.

While a plasma etching process is used in the present disclosure for illustrative purposes, it should be understood that processes described herein can be applied to other plasma processes such as film-forming depositions, etch mask creation, patterning, material etching, doping, etc.

In the preceding description, specific details have been set forth, such as a particular geometry of a processing system and descriptions of various components and processes used therein. It should be understood, however, that techniques herein may be practiced in other embodiments that depart from these specific details, and that such details are for purposes of explanation and not limitation. Embodiments disclosed herein have been described with reference to the accompanying drawings. Similarly, for purposes of explanation, specific numbers, materials, and configurations have been set forth in order to provide a thorough understanding. Nevertheless, embodiments may be practiced without such specific details. Components having substantially the same functional constructions are denoted by like reference characters, and thus any redundant descriptions may be omitted.

Various techniques have been described as multiple discrete operations to assist in understanding the various embodiments. The order of description should not be construed as to imply that these operations are necessarily order dependent. Indeed, these operations need not be performed in the order of presentation. Operations described may be performed in a different order than the described embodiment. Various additional operations may be performed and/or described operations may be omitted in additional embodiments.

“Substrate” or “wafer” as used herein generically refers to an object being processed in accordance with the invention. The substrate may include any material portion or structure of a device, particularly a semiconductor or other electronics device, and may, for example, be a base substrate structure, such as a semiconductor wafer, reticle, or a layer on or overlying a base substrate structure such as a thin film. Thus, substrate is not limited to any particular base structure, underlying layer or overlying layer, patterned or un-patterned, but rather, is contemplated to include any such layer or base structure, and any combination of layers and/or base structures. The description may reference particular types of substrates, but this is for illustrative purposes only.

The substrate can be any suitable substrate, such as a silicon (Si) substrate, a germanium (Ge) substrate, a silicon-germanium (SiGe) substrate, and/or a silicon-on-insulator (SOI) substrate. The substrate may include a semiconductor material, for example, a Group IV semiconductor, a Group III-V compound semiconductor, or a Group II-VI oxide semiconductor. The Group IV semiconductor may include Si, Ge, or SiGe. The substrate may be a bulk wafer or an epitaxial layer.

Those skilled in the art will also understand that there can be many variations made to the operations of the techniques explained above while still achieving the same objectives of the invention. Such variations are intended to be covered by the scope of this disclosure. As such, the foregoing descriptions of embodiments of the invention are not intended to be limiting. Rather, any limitations to embodiments of the invention are presented in the following claims.

What is claimed is:

1. A method of process development, the method comprising:
obtaining, from plasma parameters associated with a plasma process, one or more selected plasma parameters by executing a virtual metrology (VM) feature selection process;
obtaining a coupon recipe by adjusting a plasma process on a coupon sample based on the selected plasma parameters, the coupon sample comprising a wafer coupon positioned on a carrier wafer;
executing the coupon recipe on a first whole wafer;
obtaining a wafer recipe based on first values of the selected plasma parameters for the coupon recipe and the coupon sample, second values of the selected plasma parameters for the wafer recipe and the first whole wafer, and control models that describe relationships between the selected plasma parameters and recipe parameters of the plasma process; and
executing the wafer recipe on a second whole wafer to determine whether the second whole wafer meets a pre-determined requirement.

2. The method of claim 1, wherein the executing the VM feature selection process comprises:
determining key predictor parameters of the plasma process;
selecting a subset of the key predictor parameters based on target metrology variables;
building a set of virtual metrology (VM) models on the subset of the key predictor parameters;
selecting a subset of the VM models based on prediction accuracy; and
determining the selected plasma parameters based on calculated feature importance.

3. The method of claim 2, wherein the determining the selected plasma parameters comprises:
calculating feature importance values for variables with SHAP (SHapley Additive explanations) for each of the subset of the VM models; and
ranking the feature importance values to determine the selected plasma parameters.

4. The method of claim 3, further comprising:
executing a multi-variant linear regression with an exhaustive search for each target variable; and
cross-validating to select the subset of key predictor parameters.

5. The method of claim 4, further comprising:
building the set of VM models with an exhaustive search using cross-validation; and
ranking the set of VM models based on the prediction accuracy to select the subset of the VM models.

6. The method of claim 3, wherein:
the selected plasma parameters consist of one, two, three, four or five plasma parameters of interest.

7. The method of claim 2, wherein the determining the key predictor parameters comprises:
determining a first subgroup of predictor parameters using domain knowledge including knowledge of the plasma process, a processing tool associated with the plasma process, a metrology tool, the coupon sample, the first whole wafer, or a combination thereof;
determining a second subgroup of predictor parameters based on Design of Experiments (DOE) and the domain knowledge;
obtaining a third subgroup of predictor parameters by processing manufacturing data collected from the processing tool;
obtaining a fourth subgroup of predictor parameters by determining interaction terms of at least two predictor parameters selected from the group consisting of the first subgroup of predictor parameters, the second subgroup of predictor parameters and the third subgroup of predictor parameters, using the domain knowledge;
obtaining a fifth subgroup of predictor parameters by processing the first subgroup of predictor parameters, the second subgroup of predictor parameters, the third subgroup of predictor parameters and the fourth subgroup of predictor parameters to generate interaction terms, mathematical transformation or a combination thereof; and
removing collinearity among the first subgroup of predictor parameters, the second subgroup of predictor parameters, the third subgroup of predictor parameters, the fourth subgroup of predictor parameters and the fifth subgroup of predictor parameters to obtain the key predictor parameters.

8. The method of claim 1, wherein the obtaining the coupon recipe comprises:
adjusting the recipe parameters of the plasma process so that the coupon sample, having been subjected to the coupon recipe obtained, meets the pre-determined requirement.

9. The method of claim 1, wherein the obtaining the wafer recipe comprises:
determining difference between the first values of the selected plasma parameters for the coupon recipe and the coupon sample and the second values of the selected plasma parameters for the wafer recipe and the first whole wafer;
determining a required change to the coupon recipe based on the difference using the control models; and
adding the required change to the coupon recipe to obtain the wafer recipe.

10. The method of claim 1, further comprising:
obtaining plasma parameters of interest and corresponding control models based on blanket film data of the plasma process, wherein the selected plasma parameters are obtained by executing the VM feature selection process with coupon data of the plasma process on the coupon sample; and
when the plasma parameters of interest and the selected plasma parameters match with each other, selecting the corresponding control models as the control models.

11. The method of claim 10, further comprising:
when the plasma parameters of interest and the selected plasma parameters do not match with each other, providing a new carrier wafer.

12. The method of claim 10, further comprising:
when the second whole wafer does not meet the pre-determined requirement, re-determining the selected plasma parameters by re-executing the VM feature selection process.

13. The method of claim 10, wherein the obtaining the plasma parameters of interest and the corresponding control models comprises:
executing a Design of Experiments (DOE) process on the blanket film data of the plasma process;
executing the VM feature selection process to determine the plasma parameters of interest; and
building the corresponding control models for the plasma parameters of interest.

14. The method of claim 1, further comprising:
executing a baseline recipe respectively on a plurality of carrier wafers;
executing the baseline recipe on a third whole wafer; and
selecting the carrier wafer from the plurality of carrier wafers based on values of the selected plasma parameters for the third whole wafer and values of the selected plasma parameters for each of the plurality of carrier wafers.

15. The method of claim 14, further comprising:
inspecting the plurality of carrier wafers to obtain at least a subset of carrier wafers that match with historic data to execute the baseline recipe on.

16. The method of claim 1, further comprising:
when the second whole wafer meets the pre-determined requirement, executing the wafer recipe on one or more additional whole wafers.

17. The method of claim 1, wherein:
the plasma process comprises a plasma etching process, and
the pre-determined requirement comprises a target range of an etching rate.

18. The method of claim 17, wherein:
the carrier wafer is similar to the first whole wafer in terms of a mask material, a target etching material, an open area ratio, an aspect ratio, or a combination thereof.

19. The method of claim 18, wherein:
the mask material comprises a hardmask material, and
the target etching material comprises silicon oxide or silicon nitride.

20. An apparatus, comprising a controller which includes a processor that is programmed to:
obtain, from plasma parameters associated with a plasma process, one or more selected plasma parameters by executing a virtual metrology (VM) feature selection process;
obtain a coupon recipe by adjusting a plasma process on a coupon sample based on the selected plasma parameters, the coupon sample comprising a wafer coupon positioned on a carrier wafer;
execute the coupon recipe on a first whole wafer;
obtain a wafer recipe based on first values of the selected plasma parameters for the coupon recipe and the coupon sample, second values of the selected plasma parameters for the wafer recipe and the first whole wafer, and control models that describe relationships between the selected plasma parameters and recipe parameters of the plasma process; and
execute the wafer recipe on a second whole wafer to determine whether the second whole wafer meets a pre-determined requirement.
